(19) United States
(12) Patent Application Publication
(10) Pub. No.: US 2026/0203061 A1
(43) Pub. Date: Jul. 16, 2026

(54) ADDRESS CONTROL CIRCUIT INCLUDING ADDRESS REGISTER, METHOD OF OPERATING THE SAME, AND STORAGE CONTROLLER HAVING THE SAME

(71) Applicant: Samsung Electronics Co., Ltd., Suwon-si (KR)

(72) Inventors: Dong-Ho LEE, Suwon-si (KR); Duheon CHOI, Suwon-si (KR); Jung-Ho SONG, Suwon-si (KR); Yohan PARK, Suwon-si (KR); Youngho SEO, Suwon-si (KR)

(21) Appl. No.: 19/437,493

(22) Filed: Dec. 31, 2025

(30) Foreign Application Priority Data
Jan. 10, 2025 (KR) 10-2025-0004015

(51) Int. Cl. G06F 9/30; G06F 12/06

(52) U.S. Cl. CPC G06F 9/3013; G06F 9/30043; G06F 12/0653; G06F 2212/1021

(57) ABSTRACT

A storage controller includes a processor that generates a first address, a first memory device that stores a first instruction corresponding to the first address, a second memory device, and an address control circuit. The address control circuit is configured to receive the first address from the processor, to determine whether first address replacement information of the first address is registered in an address register of the address control circuit, to provide the first address to the first memory device in response to determining that the first address replacement information is not registered, and to provide a first replace address corresponding to the first address to the second memory device based on the first address replacement information in response to determining that the first address replacement information is registered.

### CROSS-REFERENCE TO RELATED APPLICATION

This application claims priority under 35 U.S.C. § 119 to Korean Patent Application No. 10-2025-0004015, filed on January 10, 2025, in the Korean Intellectual Property Office, the entirety of which is incorporated by reference herein.

### BACKGROUND

A memory device stores data in response to a write request and outputs data stored therein in response to a read request. For example, the memory device is classified as a volatile memory device, which loses data stored therein when a power supply is turned off, such as a dynamic random access memory (DRAM) or a static RAM (SRAM), or a non-volatile memory device, which retains data stored therein even when a power supply is turned off, such as a flash memory device, a phase-change RAM (PRAM), a magnetic RAM (MRAM), or a resistive RAM (RRAM).

The non-volatile memory device may be referred to as a “storage device” for storing a large amount of data. The storage device may include a processor and a memory device. The memory device may store instructions. The memory device may receive an address from the processor and may provide the processor with an instruction to be executed on the processor based on the received address. The ease of replacement of instructions stored in the memory device may vary depending on an operating type of the memory device.

### SUMMARY

Some aspects of the present disclosure provide address control circuits including an address register; methods of operating the same; and storage controllers including the same. For example, some aspects of this disclosure provide devices and methods of flexibly managing instructions stored in a memory device of a storage device, providing efficient operation of a processor of the storage device.

According to some implementations of the present disclosure, a storage controller is provided. The storage controller includes a processor that generates a first address, a first memory device that stores a first instruction corresponding to the first address, a second memory device, and an address control circuit. The address control circuit is configured to receive the first address from the processor, to determine whether first address replacement information of the first address is registered in an address register of the address control circuit, to provide the first address to the first memory device in response to determining that the first address replacement information is not registered, and to provide a first replace address corresponding to the first address to the second memory device based on the first address replacement information in response to determining that the first address replacement information is registered.

According to some implementations of the present disclosure, an address control circuit is provided. The address control circuit is configured to receive a first address from a processor, to determine whether first address replacement information of the first address is registered in an address register of the address control circuit, to provide the first address to a first memory device in response to determining that the first address replacement information is not registered, and to provide a first replace address corresponding to the first address to a second memory device based on the first address replacement information in response to determining that the first address replacement information is registered.

According to some implementations of the present disclosure, an operating method of an address control circuit is provided. The operating method of the address control circuit includes receiving a first address from a processor, determining whether first address replacement information of the first address is registered in an address register of the address control circuit, providing the first address to a first memory device in response to determining that the first address replacement information is not registered, and providing a first replace address corresponding to the first address to a second memory device based on the first address replacement information in response to determining that the first address replacement information is registered.

### BRIEF DESCRIPTION OF THE DRAWINGS

FIG. 1 is a block diagram illustrating an example of an electronic device.

FIG. 2 is a diagram illustrating an example of a storage controller.

FIG. 3 is a diagram illustrating an example of a storage controller.

FIG. 4 is a diagram illustrating an example of an operating method of a storage controller.

FIG. 5 is a diagram illustrating an example of an operating method of a storage controller.

FIG. 6 is a diagram illustrating an example of an operating method of a storage controller.

FIG. 7 is a diagram illustrating an example of an operating method of a storage controller.

FIG. 8 is a flowchart illustrating an example of an operating method of a storage controller.

FIG. 9 is a flowchart illustrating an example of an operating method of a storage controller.

FIG. 10 is a diagram illustrating an example of an operating method of a storage controller including unit registers.

FIG. 11 is a diagram illustrating an example of an operating method of a storage controller.

### DETAILED DESCRIPTION

The terms “unit”, “module”, etc. used below, and function blocks illustrated in drawings, may be implemented in the form of a software component, a hardware component, or a combination thereof. In some implementations, the software may be a machine code, firmware, an embedded code, or application software. In some implementations, the hardware may be or include an electrical circuit, an electronic circuit (an analog circuit or a digital circuit), a processor, a computer, an integrated circuit, integrated circuit cores, a pressure sensor, an inertial sensor, a microelectromechanical system (MEMS), a passive element, and/or a combination thereof.

Below, to describe the technical ideas of the present disclosure clearly, repeated descriptions associated with identical or substantially similar components will be omitted.

As used herein, including the claims, each of the expressions “A or B”, “at least one of A and B”, “at least one of A or B”, “A, B, or C”, “at least one of A, B, and C”, and “at least one of B or C” may include any of the items listed together in the expressions, or any possible combination thereof.

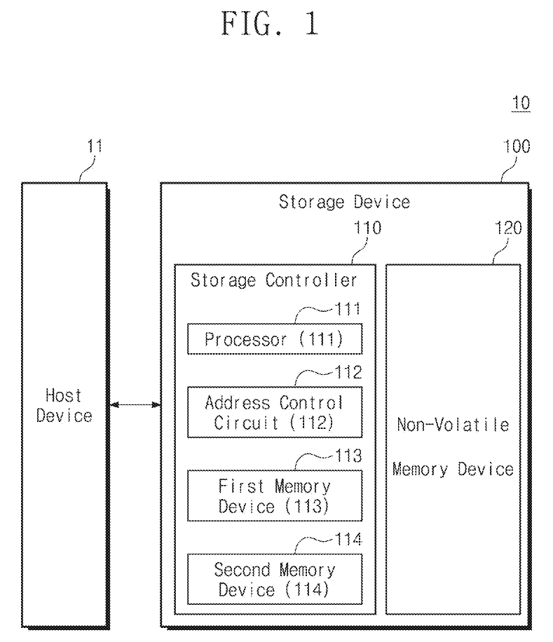

FIG. 1 is a block diagram illustrating an example of an electronic device. Referring to FIG. 1, an electronic device 10 may include a host device 11 and a storage device 100. The electronic device 10 may be a device configured to manage user data (e.g., large amounts of user data), such as a storage system, a server system, or a database server. The user data may include various pieces of information provided to users, such as images, videos, text, and voice.

The host device 11 may control overall operations of the storage device 100. For example, the host device 11 may store user data in the storage device 100, may read user data stored in the storage device 100, or may manage hardware information of the storage device 100 to maintain reliability of the user data stored in the storage device 100.

For example, the host device 11 may include a host processor and a host memory. The host processor may be implemented as a computational device such as a central processing unit (CPU), a graphic processing unit (GPU), or a neural processing unit (NPU).

The storage device 100 may include a storage controller 110 and a non-volatile memory device 120. The storage controller 110 may include a processor 111, an address control circuit 112, a first memory device 113, and a second memory device 114.

The storage controller 110 may perform a memory operation or a device management operation on the non-volatile memory device 120 based on a request of the host device 11, an internal operating policy, or an operating algorithm of an internal firmware module. The memory operation may refer to an operation related to data processing, such as a write operation, a read operation, or a delete operation. The device management operation may refer to an operation for managing the non-volatile memory device 120, such as an initialization operation, a reset operation, a status check operation, or a data reliability maintenance operation.

The processor 111 may control overall operations of the storage controller 110. The processor 111 may implement one or more functions of the storage controller 110 by executing instructions. For example, the processor 111 may perform the operating algorithm of the internal firmware module by executing an instruction.

The processor 111 may provide an address corresponding to an instruction to the address control circuit 112. The address may be used to access the instruction. The address control circuit 112 may selectively provide addresses to the first memory device 113 and the second memory device 114 based on the received address.

The address control circuit 112 may receive an address from the processor 111, may determine whether an instruction corresponding to the address has been replaced, and may access the first memory device 113 or the second memory device 114 based on whether the instruction has been replaced.

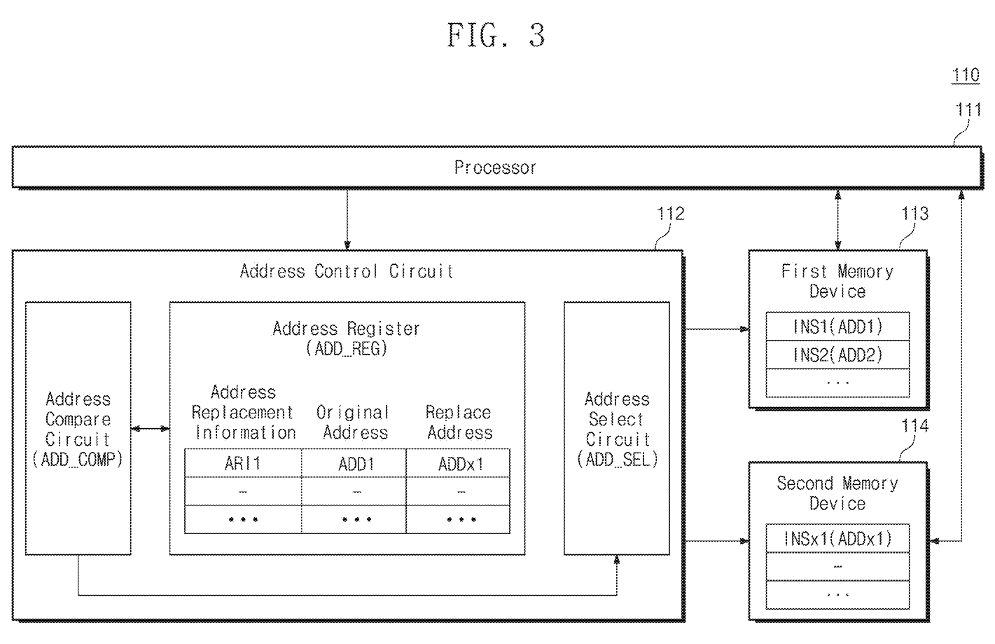

The address control circuit 112 may register address replacement information (ARI) indicating that an address of the first memory device 113 has been replaced with an address of the second memory device 114, under the control of the processor 111. A detailed description of the address control circuit 112 is provided below with reference to FIG. 3.

The first memory device 113 may store an instruction. The stored instruction may be accessed based on the corresponding address. For example, the first memory device 113 may be a Read Only Memory (ROM) device. The first memory device 113 may store instructions in a read-only type.

For example, the first memory device 113 may receive an address from the processor 111 or the address control circuit 112. The first memory device 113 may provide an instruction corresponding to the address to the processor 111.

The second memory device 114 may store an instruction. The stored instruction may be accessed based on the corresponding address. For example, the second memory device 114 may be a Random Access Memory (RAM) device. Replacing an instruction in the second memory device 114 may be easier than replacing an instruction in the first memory device 113. The second memory device 114 may store the replaced instruction.

For example, the processor 111 may request instruction replacement based on the internal operating policy, an operation of the internal firmware module, or a request of the host device 11. To execute the replaced instruction instead of the instruction stored in the first memory device 113, the processor 111 may store the replaced instruction in the second memory device 114 and may request the address control circuit 112 to change an address (e.g., a corresponding address).

In some implementations, the replaced instruction received by the processor 111 may be provided from the host device 11 or the non-volatile memory device 120. For example, the non-volatile memory device 120 may store the replaced instruction and may provide the replaced instruction to the processor 111 based on a request of the processor 111.

The non-volatile memory device 120 may store data. The non-volatile memory device 120 may operate under the control of the storage controller 110.

In some implementations, the non-volatile memory device 120 may be a flash memory device, but the present disclosure is not limited thereto. For example, the non-volatile memory device 120 may be one of various storage devices, which retain data stored therein even though a power is turned off, such as a PRAM, an MRAM, a RRAM, and an FRAM.

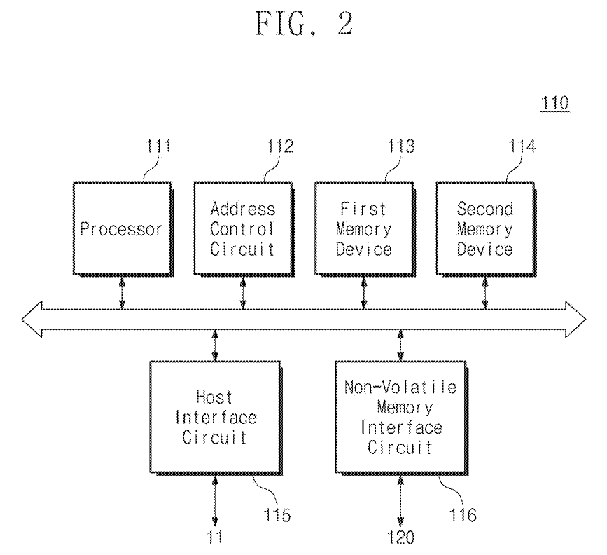

FIG. 2 is a diagram for describing an example of a storage controller. Referring to FIGS. 1 and 2, the storage controller 110 may communicate with the host device 11 and the non-volatile memory device 120.

The storage controller 110 may include the processor 111, the address control circuit 112, the first memory device 113, the second memory device 114, a host interface circuit 115, and a non-volatile memory interface circuit 116.

The processor 111, the address control circuit 112, the first memory device 113, and the second memory device 114 are similar to the processor 111, the address control circuit 112, the first memory device 113, and the second memory device 114 in FIG. 1, and thus, detailed redundant descriptions are omitted below.

The storage controller 110 may communicate with external devices through the host interface circuit 115 and the non-volatile memory interface circuit 116.

The host interface circuit 115 may communicate with the host device 11 and the storage controller 110. For example, the host device 11 may provide an instruction to the host interface circuit 115. The host interface circuit 115 may provide the received instruction to the processor 111. The processor 111 may provide the received instruction to the second memory device 114, and may store the instruction in the second memory device 114.

In some implementations, the host interface circuit 115 may be implemented based on at least one of various interfaces such as a SATA (Serial ATA) interface, a PCIe (Peripheral Component Interconnect Express) interface, a SAS (Serial Attached SCSI), an NVMe (Nonvolatile Memory express) interface, or an UFS (Universal Flash Storage) interface.

The non-volatile memory interface circuit 116 may communicate with the non-volatile memory device 120. For example, the non-volatile memory device 120 may provide an instruction to the non-volatile memory interface circuit 116. The non-volatile memory interface circuit 116 may provide the received instruction to the processor 111. The processor 111 may provide the received instruction to the second memory device 114, and may store the instruction in the second memory device 114.

In some implementations, physical paths connected to a plurality of memory chips within the non-volatile memory device 120 may pass through the non-volatile memory interface circuit 116. The non-volatile memory interface circuit 116 may be implemented based on a NAND interface.

FIG. 3 is a diagram illustrating an example of a storage controller. Referring to FIG. 3, the storage controller 110 may include the processor 111, the address control circuit 112, the first memory device 113, and the second memory device 114.

The processor 111 may control overall operations of the storage controller 110. The processor 111 may implement one or more functions of the storage controller 110 by executing an instruction. For example, the first memory device 113 may store a first instruction INS1. The first memory device 113 may provide the first instruction INS1 to the processor 111. The processor 111 may implement at least one function of the storage controller 110 by executing the received first instruction INS1.

The processor 111 may provide an address corresponding to an instruction to the address control circuit 112. The address may be used to access the instruction. The address control circuit 112 may selectively provide addresses to the first memory device 113 and the second memory device 114 based on the received address.

The address control circuit 112 may receive an address from the processor 111, may determine whether an instruction corresponding to the address has been replaced, and may access the first memory device 113 or the second memory device 114 based on whether the instruction has been replaced.

The address control circuit 112 may include an address compare circuit ADD_COMP, an address register ADD_REG, and an address select circuit ADD_SEL.

The address register ADD_REG may register address replacement information under the control of the processor 111. The address replacement information may indicate that an address of the first memory device 113 has been replaced with an address of the second memory device 114. For example, the address replacement information may include mapping information between an address and a replace address. For example, the address register ADD_REG may register first address replacement information ARI1 of a first address ADD1. The first address replacement information ARI1 may indicate that the first address ADD1 of the first memory device 113 has been replaced with a first replace address ADDx1 of the second memory device 114.

The address compare circuit ADD_COMP may determine whether address replacement information (e.g., corresponding to a provided address) is registered in the address register ADD_REG. The address compare circuit ADD_COMP may provide a miss signal to the address select circuit ADD_SEL in response to determining that address replacement information is not registered in the address register ADD_REG. On the other hand, the address compare circuit ADD_COMP may provide a hit signal to the address select circuit ADD_SEL in response to determining that address replacement information has been registered in the address register ADD_REG.

The hit signal may indicate that the address replacement information corresponding to the address received by the address control circuit 112 has been registered in the address register ADD_REG. The miss signal may indicate that the address replacement information corresponding to the address received by the address control circuit 112 is not registered in the address register ADD_REG.

The address select circuit ADD_SEL may receive the miss signal or the hit signal from the address compare circuit ADD_COMP. The address select circuit ADD_SEL may selectively provide addresses to the first memory device 113 and the second memory device 114 in response to the received miss signal or the received hit signal. For example, the address select circuit ADD_SEL may provide the first address ADD1 to the first memory device 113 in response to the miss signal, and may provide the first replace address ADDx1 to the second memory device 114 in response to the hit signal.

In some implementations, the address select circuit ADD_SEL may provide the received address to both the first memory device 113 and the second memory device 114 in response to the miss signal.

The first memory device 113 may store an instruction. The stored instruction may be accessed based on the corresponding address. For example, the first memory device 113 may store the first instruction INS1. The first instruction INS1 may correspond to (e.g., be stored at) the first address ADD1.

For example, the first memory device 113 may receive an address from the processor 111 or the address control circuit 112. The first memory device 113 may provide an instruction corresponding to the address to the processor 111. For example, the address control circuit 112 may provide the first address ADD1 to the first memory device 113. The first memory device 113 may provide the first instruction INS1 corresponding to the first address ADD1 (e.g., stored at the first address ADD1) to the processor 111.

In some implementations, the first memory device 113 may be a ROM device. The first memory device 113 may store instructions in a read-only type. As such, it may be difficult to replace instructions stored in the first memory device 113 and/or add instructions to the first memory device 113.

The second memory device 114 may store the instruction. The stored instruction may be accessed based on the corresponding address. For example, the second memory device 114 may store a first replacement instruction INSx1. The first replacement instruction INSx1 may correspond to the first replace address ADDx1.

Replacing an instruction in the second memory device 114 may be easier than replacing an instruction in the first memory device 113. The second memory device 114 may store the replaced instruction. For example, the first replacement instruction INSx1 stored in the second memory device 114 may be an instruction that replaces the first instruction INS1 stored in the first memory device 113.

For example, the processor 111 may request instruction replacement based on the internal operating policy, an operation of the internal firmware module, or a request of the host device 11. To execute the replaced instruction instead of the instruction stored in the first memory device 113, the processor 111 may store the replaced instruction in the second memory device 114 and may request the address control circuit 112 to change an address.

In some implementations, the replaced instruction received by the processor 111 may be provided from the host device 11 or the non-volatile memory device 120. For example, the non-volatile memory device 120 may store the replaced instruction and may provide the replaced instruction to the processor 111 based on a request of the processor 111.

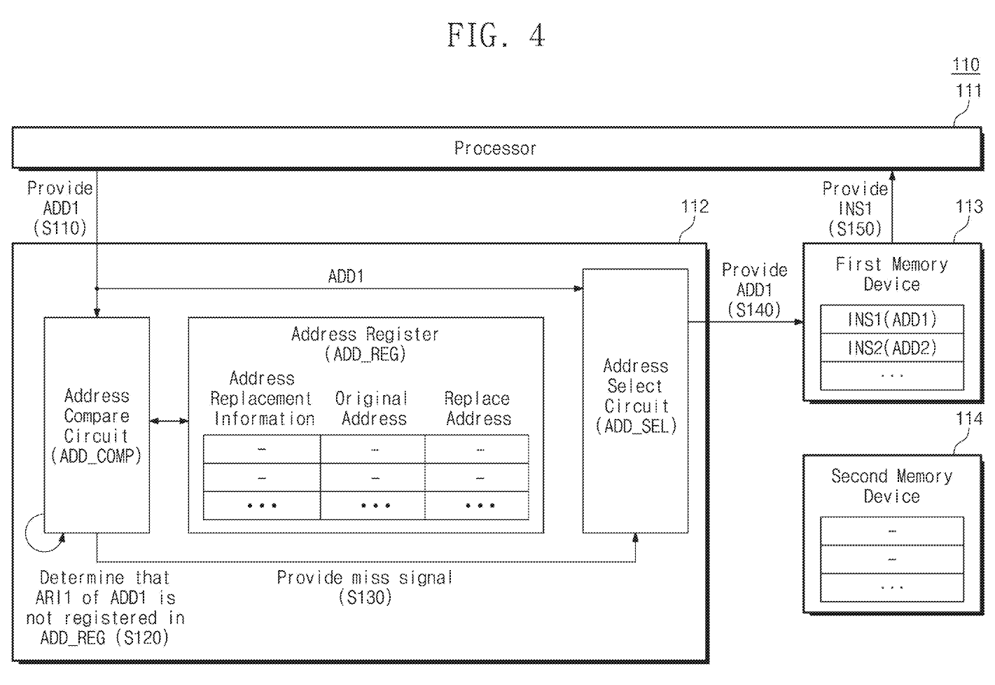

FIG. 4 is a diagram illustrating an example of an an operating method of a storage controller. Referring to FIG. 4, the storage controller 110 may include the processor 111, the address control circuit 112, the first memory device 113, and the second memory device 114. The processor 111, the address control circuit 112, the first memory device 113, and the second memory device 114 are similar to the processor 111, the address control circuit 112, the first memory device 113, and the second memory device 114 in FIG. 3, and thus, redundant descriptions are omitted below.

The address control circuit 112 may include the address compare circuit ADD_COMP, the address register ADD_REG, and the address select circuit ADD_SEL. The address compare circuit ADD_COMP, the address register ADD_REG, and the address select circuit ADD_SEL are similar to the address compare circuit ADD_COMP, the address register ADD_REG, and the address select circuit ADD_SEL of FIG. 3, and thus, redundant descriptions are omitted below.

The processor 111 may control overall operations of the storage controller 110. The processor 111 may implement one or more functions of the storage controller 110 by executing an instruction.

The address control circuit 112 may determine whether the received first address ADD1 is a replacement target address. For example, the address control circuit 112 may determine whether the first address replacement information ARI1 of the first address ADD1 is registered in the address register ADD_REG.

The first memory device 113 may store the first instruction INS1 corresponding to the first address ADD1. The first memory device 113 may store a second instruction INS2 corresponding to a second address ADD2.

Hereinafter, an example of an operating method of the storage controller 110 based on the address control of the address control circuit 112 will be described. Specifically, a method according to which the storage controller 110 operates when it is not determined that address replacement information corresponding to an address received in the address register ADD_REG is present is described.

In operation S110, the processor 111 may provide the first address ADD1 to the address control circuit 112. For example, the processor 111 may provide the first address ADD1 to the address compare circuit ADD_COMP and the address select circuit ADD_SEL.

In operation S120, the address compare circuit ADD_COMP may determine that the first address replacement information ARI1 of the first address ADD1 is not registered in the address register ADD_REG. The first address replacement information ARI1 may indicate that the first address ADD1 is a replacement target address.

In operation S130, the address compare circuit ADD_COMP may provide a miss signal to the address select circuit ADD_SEL in response to determining that the first address replacement information ARI1 is not registered in the address register ADD_REG.

In operation S140, the address select circuit ADD_SEL may provide the first address ADD1 to the first memory device 113 based on the received miss signal. For example, the address control circuit 112 may determine that the received first address ADD1 has not been replaced, and may provide the received first address ADD1 to the first memory device 113 in response to determining that the first address ADD1 has not been replaced.

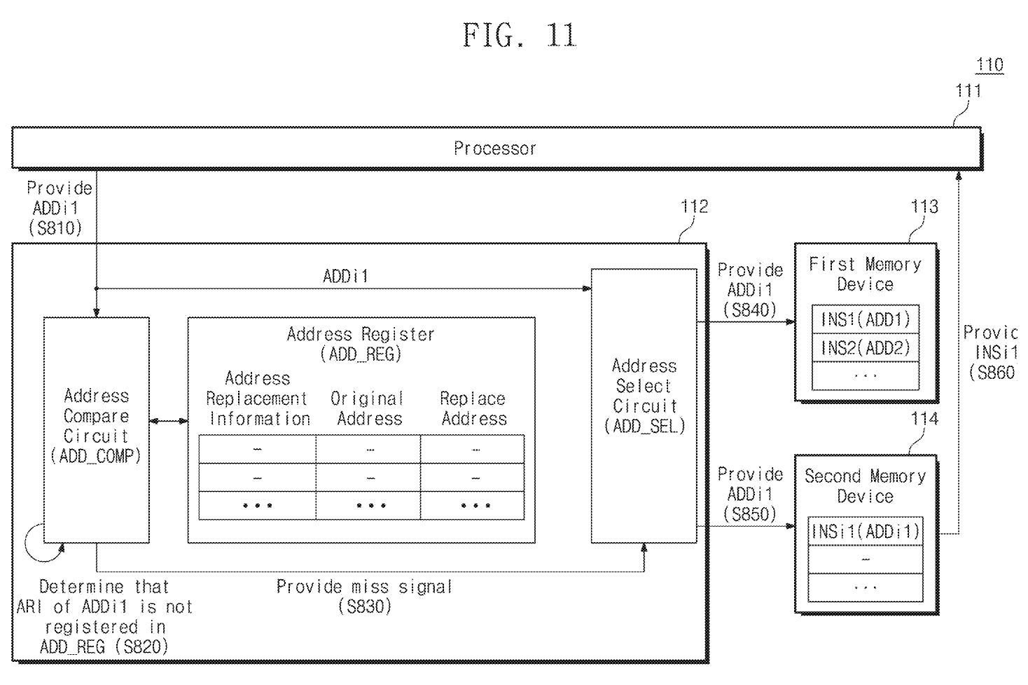

In some implementations, the address select circuit ADD_SEL may provide the first address ADD1 to the second memory device 114 based on the miss signal. A configuration for providing an address to the second memory device 114 despite the miss signal will be described below with reference to FIG. 11.

In operation S150, the first memory device 113 may access the first instruction INS1 based on the received first address ADD1, and may provide the accessed first instruction INS1 to the processor 111. The processor 111 may execute the received first instruction INS1.

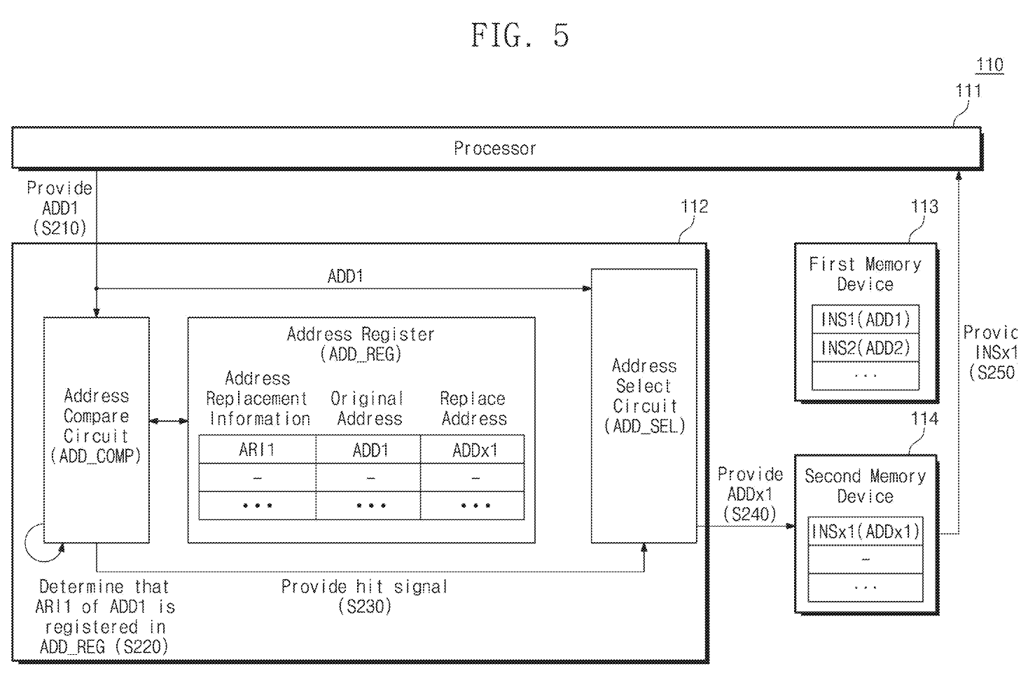

FIG. 5 is a diagram illustrating an example of an operating method of a storage controller. Referring to FIG. 5, the storage controller 110 may include the processor 111, the address control circuit 112, the first memory device 113, and the second memory device 114. The processor 111, the address control circuit 112, the first memory device 113, and the second memory device 114 are similar to the processor 111, the address control circuit 112, the first memory device 113, and the second memory device 114 in FIG. 3, and thus, redundant descriptions are omitted below.

The address control circuit 112 may include the address compare circuit ADD_COMP, the address register ADD_REG, and the address select circuit ADD_SEL. The address compare circuit ADD_COMP, the address register ADD_REG, and the address select circuit ADD_SEL are similar to the address compare circuit ADD_COMP, the address register ADD_REG, and the address select circuit ADD_SEL of FIG. 3, and thus, redundant descriptions are omitted below.

The processor 111 may control overall operations of the storage controller 110. The processor 111 may implement one or more functions of the storage controller 110 by executing an instruction.

The address control circuit 112 may register the first address replacement information ARI1 corresponding to the received first address ADD1. The first address replacement information ARI1 may indicate that the first address ADD1 is a replacement target address.

The first memory device 113 may store the first instruction INS1 corresponding to the first address ADD1. The first memory device 113 may store the second instruction INS2 corresponding to the second address ADD2.

The second memory device 114 may store the first replacement instruction INSx1 corresponding to the first replace address ADDx1. Replacing an instruction in the second memory device 114 may be easier than replacing an instruction in the first memory device 113. The first replacement instruction INSx1 may be an instruction to be executed by the processor 111 instead of the first instruction INS1.

Hereinafter, an operating method of the storage controller 110 based on the address selection of the address control circuit 112 will be described. Specifically, a method according to which the storage controller 110 operates when it is determined that address replacement information corresponding to an address received in the address register ADD_REG is present is described.

In operation S210, the processor 111 may provide the first address ADD1 to the address control circuit 112. For example, the first address ADD1 may be provided to the address compare circuit ADD_COMP and the address select circuit ADD_SEL.

In operation S220, the address compare circuit ADD_COMP may determine that the first address replacement information ARI1 of the first address ADD1 is registered in the address register ADD_REG. The first address replacement information ARI1 may indicate that the first address ADD1 of the first memory device 113 has been replaced with the first replace address ADDx1 of the second memory device 114.

In some implementations, the first address replacement information ARI1 may indicate mapping information between the first address ADD1 and the first replace address ADDx1.

In some implementations, the first address replacement information ARI1 may indicate that the first address ADD1 is registered in a first unit register of the address register ADD_REG. The first unit register may be dedicated to the first replace address ADDx1 of the second memory device 114.

In operation S230, the address compare circuit ADD_COMP may provide a hit signal to the address select circuit ADD_SEL in response to determining that the first address replacement information ARI1 is registered in the address register ADD_REG.

In some implementations, the hit signal may include the first address replacement information ARI1. The first address replacement information ARI1 may indicate that the first address ADD1 has been replaced with the first replace address ADDx1.

In operation S240, the address select circuit ADD_SEL may provide the first replace address ADDx1 to the second memory device 114 based on the hit signal.

In some implementations, the address select circuit ADD_SEL may store the first replace address ADDx1. The first replace address ADDx1 stored in the address select circuit ADD_SEL is stored when the address select circuit ADD_SEL is implemented. Therefore, it may not be easy to change the first replace address ADDx1. The address select circuit ADD_SEL may provide the first replace address ADDx1 to the second memory device 114 based on the first address replacement information ARI1.

In operation S250, the second memory device 114 may access the first replacement instruction INSx1 based on the received first replace address ADDx1, and may provide the accessed first replacement instruction INSx1 to the processor 111. The processor 111 may execute the received first replacement instruction INSx1.

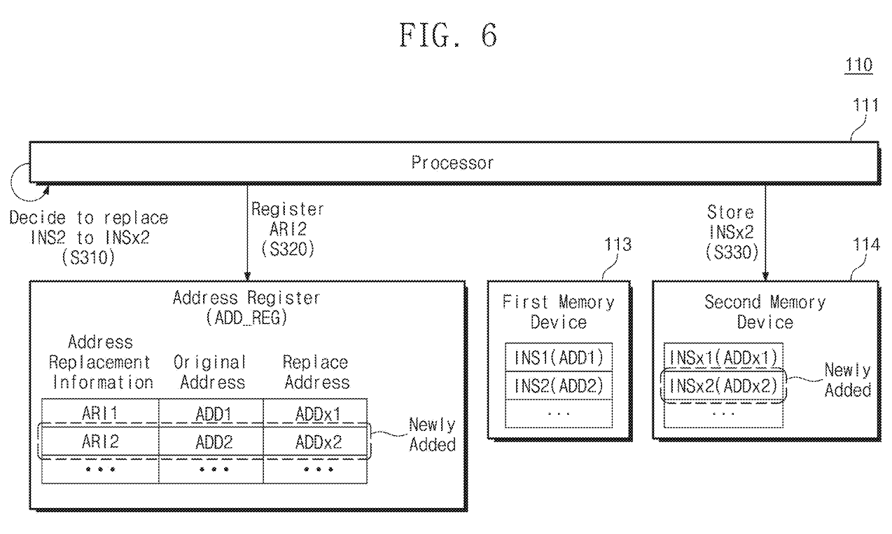

FIG. 6 is a diagram illustrating an example of an operating method of a storage controller. Referring to FIG. 6, the storage controller 110 may include the processor 111, the address register ADD_REG, the first memory device 113, and the second memory device 114. The processor 111, the address register ADD_REG, the first memory device 113, and the second memory device 114 are similar to the processor 111, the address register ADD_REG, the first memory device 113, and the second memory device 114 in FIG. 3, and thus, redundant descriptions are omitted below.

The processor 111 may control overall operations of the storage controller 110. The processor 111 may implement one or more functions of the storage controller 110 by executing an instruction.

The address register ADD_REG may register the first address replacement information ARI1 corresponding to the received first address ADD1. The first address replacement information ARI1 may indicate that the first address ADD1 is a replacement target address.

The first memory device 113 may store the first instruction INS1 corresponding to the first address ADD1. The first memory device 113 may store the second instruction INS2 corresponding to the second address ADD2.

The second memory device 114 may store the first replacement instruction INSx1 corresponding to the first replace address ADDx1. Replacing an instruction in the second memory device 114 may be easier than replacing an instruction in the first memory device 113. The first replacement instruction INSx1 may be an instruction to be executed by the processor 111 instead of the first instruction INS1.

Hereinafter, a method in which the storage controller 110 manages information of the second memory device 114 and the address register ADD_REG will be described. In more detail, a method, in which the storage controller 110 manages information of the second memory device 114 and the address register ADD_REG to execute a second replacement instruction INSx2 instead of the second instruction INS2 stored in the first memory device 113, is described.

In operation S310, the processor 111 may determine to replace the second instruction INS2 with the second replacement instruction INSx2. The second instruction INS2 may be an instruction accessed through the second address ADD2 in the first memory device 113. For example, the processor 111 may determine to replace the second instruction INS2 with the second replacement instruction INSx2 based on an internal operating policy, an operation of an internal firmware module, or a request of the host device 11 of FIG. 1.

In some implementations, the second replacement instruction INSx2 may be provided from the host device 11 of FIG. 1 or the non-volatile memory device 120 of FIG. 1.

In some implementations, the processor 111 may generate second address replacement information ARI2. The second address replacement information ARI2 may indicate that the second address ADD2 needs to be replaced with a second replace address ADDx2.

In operation S320, the processor 111 may register the second address replacement information ARI2 in the address register ADD_REG. The second address replacement information ARI2 may indicate that the second address ADD2 needs to be replaced with the second replace address ADDx2.

In some implementations, registering the second address replacement information ARI2 may refer to registering the second address ADD2 in a unit register dedicated to the second replace address ADDx2.

In operation S330, the processor 111 may store the second replacement instruction INSx2 in the second memory device 114. The second replacement instruction INSx2 may be an instruction accessed based on the second replace address ADDx2.

The storage controller 110 may register the second address replacement information ARI2 indicating that the second address ADD2 has been replaced with the second replace address ADDx2 in the address register ADD_REG, and may store the second replacement instruction INSx2, which is accessed at the second replace address ADDx2, in the second memory device 114. Accordingly, the processor 111 may execute the second replacement instruction INSx2 instead of the second instruction INS2.

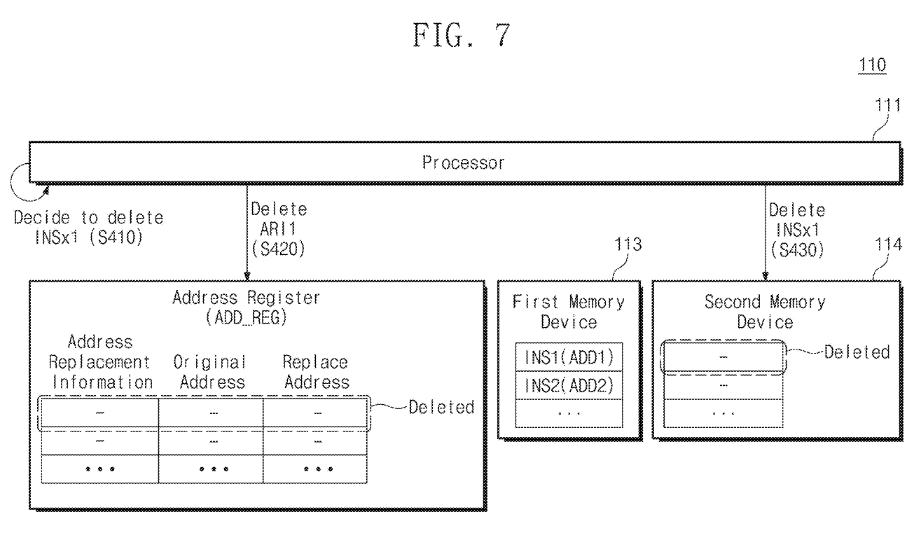

FIG. 7 is a diagram illustrating an example of an operating method of a storage controller. Referring to FIG. 7, the storage controller 110 may include the processor 111, the address register ADD_REG, the first memory device 113, and the second memory device 114. The processor 111, the address register ADD_REG, the first memory device 113, and the second memory device 114 are similar to the processor 111, the address register ADD_REG, the first memory device 113, and the second memory device 114 in FIG. 3, and thus, redundant descriptions are omitted below.

The processor 111 may control overall operations of the storage controller 110. The processor 111 may implement one or more functions of the storage controller 110 by executing an instruction.

The address register ADD_REG may register address replacement information. For example, before operations S410 to S430 are executed, the address register ADD_REG may register the first address replacement information ARI1. The first address replacement information ARI1 may indicate that the first address ADD1 has been replaced with the first replace address ADDx1.

The first memory device 113 may store the first instruction INS1 corresponding to the first address ADD1. The first memory device 113 may store the second instruction INS2 corresponding to the second address ADD2.

The second memory device 114 may store a replacement instruction. Replacing an instruction in the second memory device 114 may be easier than replacing an instruction in the first memory device 113. For example, before operations S410 to S430 are executed, the second memory device 114 may store the first replacement instruction INSx1 corresponding to the first replace address ADDx1. The processor 111 may execute the first replacement instruction INSx1 instead of the first instruction INS1.

Hereinafter, a method in which the storage controller 110 manages information of the second memory device 114 and the address register ADD_REG will be described.

In operation S410, the processor 111 may determine to delete the first replacement instruction INSx1. In other words, the processor 111 may stop using the first replacement instruction INSx1 in place of the first instruction INS1. In some implementations, the processor 111 may determine to delete the first replacement instruction INSx1 based on an internal operating policy, an operation of an internal firmware module, or a request of the host device 11.

In operation S420, the processor 111 may delete the first address replacement information ARI1 of the address register ADD_REG. The first address replacement information ARI1 may indicate that the first address ADD1 has been replaced with the first replace address ADDx1.

In operation S430, the processor 111 may delete the first replacement instruction INSx1 of the second memory device 114. The first replacement instruction INSx1 may be an instruction that replaced the first instruction INS1.

Based on execution of operations S410 to S430, the processor 111 may execute the first instruction INS1 again.

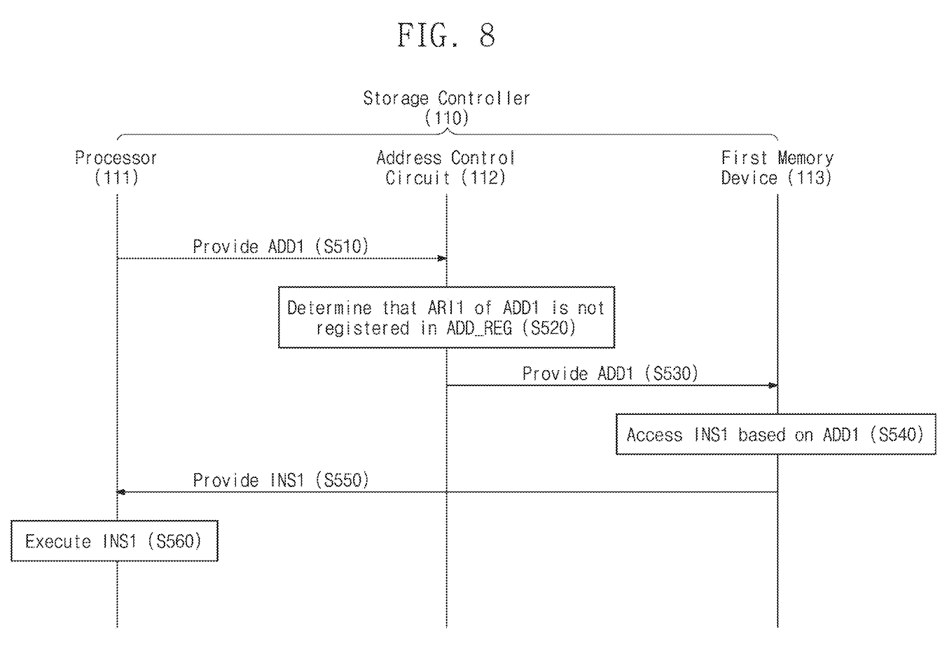

FIG. 8 is a flowchart illustrating an example of an operating method of a storage controller, e.g., the storage controller 110. The storage controller 110 may include the processor 111, the address control circuit 112, and the first memory device 113.

In operation S510, the processor 111 may provide the first address ADD1 to the address control circuit 112. The first address ADD1 may be an address of the first memory device 113. The first memory device 113 may access the first instruction INS1 based on the first address ADD1.

In operation S520, the address control circuit 112 may determine that the first address replacement information ARI1 of the first address ADD1 is not registered in the address register ADD_REG of the address control circuit 112. The address control circuit 112 may include the address register ADD_REG. The address register ADD_REG may register the first address replacement information ARI1. The first address replacement information ARI1 may indicate that the first address ADD1 received by the address control circuit 112 has been replaced.

In some implementations, the address control circuit 112 may include an address compare circuit and an address select circuit. The address compare circuit may determine whether the first address replacement information ARI1 is registered in the address register ADD_REG. The address compare circuit may provide a miss signal to the address select circuit in response to determining that the first address replacement information ARI1 is not registered in the address register ADD_REG.

In operation S530, the address control circuit 112 may provide the first address ADD1 to the first memory device 113. The first memory device 113 may store the first instruction INS1. The first memory device 113 may access the first instruction INS1 based on the received first address ADD1.

In some implementations, the address select circuit of the address control circuit 112 may receive the miss signal from the address compare circuit. The address select circuit may provide the first address ADD1 to the first memory device 113 based on the received miss signal.

In operation S540, the first memory device 113 may access the first instruction INS1 based on the first address ADD1.

In operation S550, the first memory device 113 may provide the first instruction INS1 to the processor 111. The first instruction INS1 may be accessed based on the first address ADD1.

In operation S560, the processor 111 may execute the first instruction INS1. The processor 111 may control operation (e.g., the overall operation) of the storage controller 110 by executing the first instruction INS1.

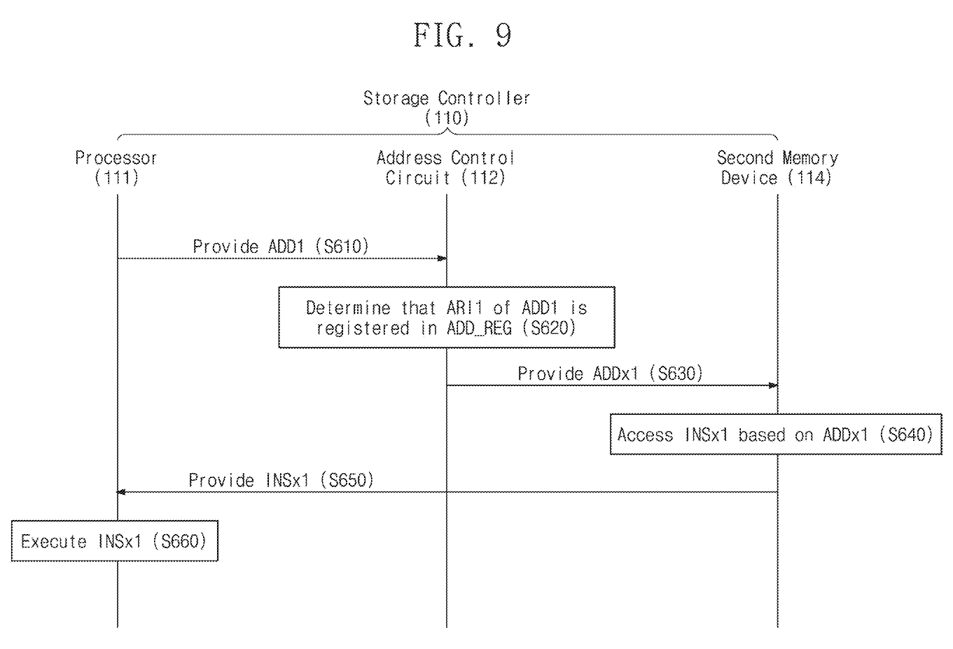

FIG. 9 is a flowchart illustrating an example of an operating method of a storage controller, such as the storage controller 110. The storage controller 110 may include the processor 111, the address control circuit 112, and the second memory device 114.

In operation S610, the processor 111 may provide the first address ADD1 to the address control circuit 112. The storage controller 110 may include a first memory device. The first memory device may store a first instruction. The first memory device may access the first instruction based on the first address ADD1.

In operation S620, the address control circuit 112 may determine that the first address replacement information ARI1 of the first address ADD1 has been registered in the address register ADD_REG of the address control circuit 112. The address control circuit 112 may receive the first address ADD1. The address control circuit 112 may include the address register ADD_REG. The address register ADD_REG may register the first address replacement information ARI1 of the first address ADD1. The first address replacement information ARI1 may indicate that the first address ADD1 has been replaced with the first replace address ADDx1. For example, the first address replacement information ARI1 may include mapping information between the first address ADD1 and the first replace address ADDx1. The address control circuit 112 may determine that the first address replacement information ARI1 has been registered in the address register ADD_REG.

In some implementations, the address control circuit 112 may include an address compare circuit and an address select circuit. The address compare circuit may determine whether the first address replacement information ARI1 is registered in the address register ADD_REG. The address compare circuit may provide a hit signal to the address select circuit in response to determining that the first address replacement information ARI1 has been registered in the address register ADD_REG.

In operation S630, the address control circuit 112 may provide the first replace address ADDx1 to the second memory device 114. In some implementations, the address select circuit may receive the hit signal from the address compare circuit, and may receive the first replace address ADDx1 from the address register ADD_REG. The address select circuit may provide the first replace address ADDx1 to the second memory device 114 in response to the hit signal.

In operation S640, the second memory device 114 may access the first replacement instruction INSx1 based on the first replace address ADDx1. The second memory device 114 may be a memory device in which an instruction is replaced (or added) more easily than the first memory device. The second memory device 114 may store the first replacement instruction INSx1. The second memory device 114 may receive the first replace address ADDx1 and may access the first replacement instruction INSx1 based on the received first replace address ADDx1.

In operation S650, the second memory device 114 may provide the first replacement instruction INSx1 to the processor 111.

In operation S660, the processor 111 may execute the first replacement instruction INSx1. The processor 111 may control operation (e.g., the overall operation) of the storage controller 110 by executing the first replacement instruction INSx1.

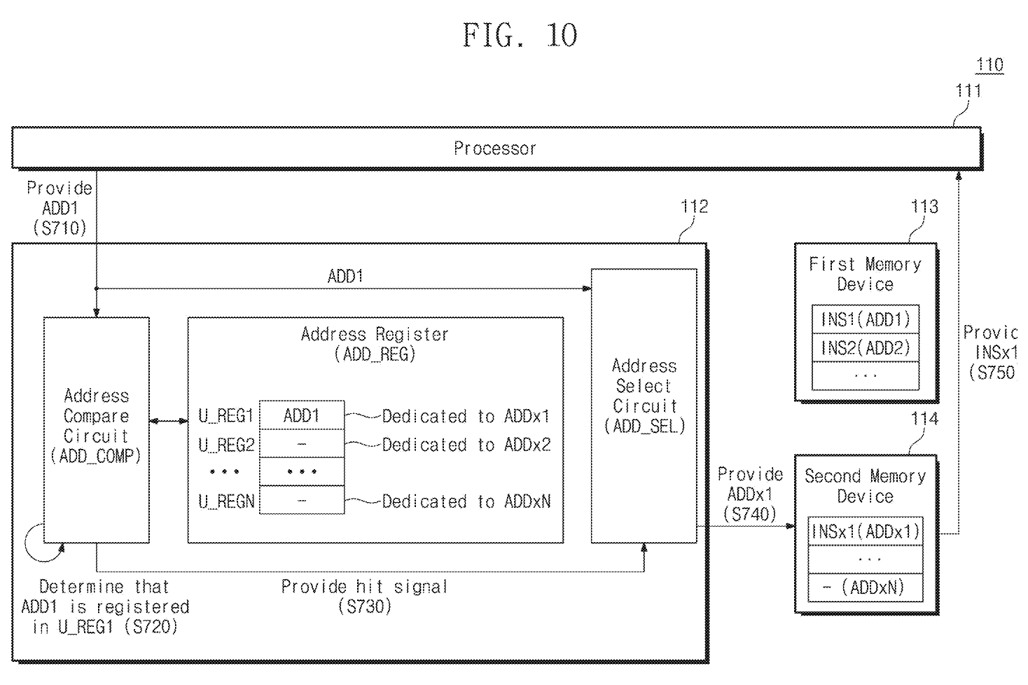

FIG. 10 is a diagram illustrating an example of an an operating method of a storage controller including unit registers. Referring to FIG. 10, the storage controller 110 may include the processor 111, the address control circuit 112, the first memory device 113, and the second memory device 114.

The processor 111 may control overall operations of the storage controller 110. The processor 111 may implement one or more functions of the storage controller 110 by executing an instruction.

The address control circuit 112 may receive an address from the processor 111, may determine whether an instruction corresponding to the address has been replaced, and may access the first memory device 113 or the second memory device 114 based on whether the instruction has been replaced.

The address control circuit 112 may include the address compare circuit ADD_COMP, the address register ADD_REG, and the address select circuit ADD_SEL.

The address register ADD_REG may register address replacement information under the control of the processor 111. The address replacement information may indicate whether the address received by the address control circuit 112 has been replaced.

The address register ADD_REG may include first to N-th unit registers U_REG1 to U_REGN. ‘N’ is a natural number. A unit register may register an address. For example, the first unit register U_REG1 may register the first address ADD1. The first address ADD1 may be used to access the first instruction INS1 in the first memory device 113.

The unit register may be dedicated to a replace address of the second memory device 114. For example, the first unit register U_REG1 may be dedicated to the first replace address ADDx1 of the second memory device 114.

The first memory device 113 may store the first instruction INS1 corresponding to the first address ADD1. The first memory device 113 may store the second instruction INS2 corresponding to the second address ADD2.

The second memory device 114 may store the first replacement instruction INSx1 corresponding to the first replace address ADDx1. Replacing (or adding) an instruction in the second memory device 114 may be easier than replacing an instruction in the first memory device 113. The first replacement instruction INSx1 may be an instruction to be executed by the processor 111 instead of the first instruction INS1.

Hereinafter, an example of an operating method of the storage controller 110 based on the address control of the address control circuit 112 will be described.

In operation S710, the processor 111 may provide the first address ADD1 to the address control circuit 112. The first address ADD1 may be used to access the first instruction INS1 in the first memory device 113. For example, the processor 111 may provide the first address ADD1 to the address compare circuit ADD_COMP and the address select circuit ADD_SEL.

In operation S720, the address compare circuit ADD_COMP may determine that the first address ADD1 is registered in the first unit register U_REG1. The first unit register U_REG1 may be dedicated to the first replace address ADDx1 of the second memory device 114.

In some implementations, address replacement information of the first address ADD1 may indicate that the first address ADD1 is registered in the first unit register U_REG1 dedicated to the first replace address ADDx1.

In operation S730, the address compare circuit ADD_COMP may provide a hit signal to the address select circuit ADD_SEL in response to determining that the received first address ADD1 is registered in the first unit register U_REG1. The hit signal may indicate that the received first address ADD1 has been registered in the first unit register U_REG1.

In operation S740, the address select circuit ADD_SEL may provide the first replace address ADDx1 to the second memory device 114 based on the hit signal. For example, the address select circuit ADD_SEL may provide the second memory device 114 with the first replace address ADDx1 dedicated by the first unit register U_REG1 in response to a hit signal indicating that the first address ADD1 has been registered in the first unit register U_REG1, e.g., based on the first replace address ADDx1 corresponding to the first unit register U_REG1.

In some implementations, the first to N-th unit registers U_REG1 to U_REGN may be dedicated to first to N-th replace addresses ADDx1 to ADDxN of the second memory device 114, respectively. The address select circuit ADD_SEL may store mapping relationships between the first to N-th unit registers U_REG1 to U_REGN and the first to N-th replace addresses ADDx1 to ADDxN.

For example, the hit signal provided from the address compare circuit ADD_COMP to the address select circuit ADD_SEL may include only identification information of the first unit register U_REG1 in which the first address ADD1 is registered. The first replace address ADDx1 may be a fixed address and may be inserted when the address select circuit ADD_SEL is implemented. For example, the first replace address ADDx1 may be a fixed circuit area of the address select circuit ADD_SEL. The address select circuit ADD_SEL may provide the inserted first replace address ADDx1 to the second memory device 114 based on the identification information of the first unit register U_REG1.

In operation S750, the second memory device 114 may provide the first replacement instruction INSx1 to the processor 111. The second memory device 114 may access the stored first replacement instruction INSx1 based on the received first replace address ADDx1.

The second memory device 114 may provide the accessed first replacement instruction INSx1 to the processor 111.

The address control circuit 112 may determine that the received first address ADD1 is a replacement target address and may provide the first replace address ADDx1 to the second memory device 114 instead of the first memory device 113 in response thereto. Accordingly, the processor may execute the first replacement instruction INSx1 instead of the first instruction INS1.

In some implementations, the implementation area of the address control circuit 112 may be reduced by utilizing a fixed address configuration in the address select circuit ADD_SEL, e.g., while information about the first replace address ADDx1 is not registered in the address register ADD_REG.

FIG. 11 is a diagram illustrating an example of an operating method of a storage controller, such as the storage controller 110. Referring to FIG. 11, the storage controller 110 may include the processor 111, the address control circuit 112, the first memory device 113, and the second memory device 114.

The processor 111 may control overall operations of the storage controller 110. The processor 111 may implement one or more functions of the storage controller 110 by executing an instruction.

The address control circuit 112 may receive an address from the processor 111 and may determine whether an instruction corresponding to the address has been replaced. The address control circuit 112 may include the address compare circuit ADD_COMP, the address register ADD_REG, and the address select circuit ADD_SEL.

The first memory device 113 may store the first instruction INS1 corresponding to the first address ADD1. The first memory device 113 may store the second instruction INS2 corresponding to the second address ADD2.

The second memory device 114 may store a first independent instruction INSi1 corresponding to a first independent address ADDi1. The first independent instruction INSi1 may be an instruction independent of an instruction stored in the first memory device 113, e.g., may not be a replacement instruction.

For better understanding of the present disclosure, FIG. 11 illustrates that the second memory device 114 stores only the first independent instruction INSi1, but the present disclosure is not limited thereto. The second memory device 114 may store one or more independent instructions and one or more replacement instructions. A replacement instruction may refer to an instruction that replaces an instruction stored in the first memory device 113.

Hereinafter, an example of an operating method of the storage controller 110 based on the address control of the address control circuit 112 will be described.

In operation S810, the processor 111 may provide the first independent address ADDi1 to the address control circuit 112. The first independent address ADDi1 may be used to access the first independent instruction INSi1 in the second memory device 114. For example, the processor 111 may provide the first independent address ADDi1 to the address compare circuit ADD_COMP and the address select circuit ADD_SEL.

In operation S820, the address compare circuit ADD_COMP may determine that address replacement information corresponding to the first independent address ADDi1 is not registered in the address register ADD_REG.

In some implementations, the address register ADD_REG may include a plurality of unit registers. The fact that the address replacement information of the first independent address ADDi1 is not registered in the address register ADD_REG may indicate that the first independent address ADDi1 is not registered in any of the unit registers.

In operation S830, the address compare circuit ADD_COMP may provide a miss signal to the address select circuit ADD_SEL. The miss signal may indicate that the address replacement information of the first independent address ADDi1 is not registered in the address register ADD_REG.

In operation S840, the address select circuit ADD_SEL may provide the first independent address ADDi1 received to the first memory device 113. In some implementations, the first independent address ADDi1 may not be an address of the first memory device 113, and thus the first memory device 113 may not access an instruction even when receiving the first independent address ADDi1.

In operation S850, the address select circuit ADD_SEL may provide the received first independent address ADDi1 to the second memory device 114. The second memory device 114 may access the first independent instruction INSi1 based on the first independent address ADDi1.

In operation S860, the second memory device 114 may provide the first independent instruction INSi1 to the processor 111. The first independent instruction INSi1 may be an instruction accessed based on the first independent address ADDi1 in the second memory device 114. The processor 111 may execute the first independent instruction INSi1.

Accordingly, in some implementations, even when address replacement information corresponding to the received address is not registered, the address control circuit 112 may provide the received address to both the first memory device 113 and the second memory device 114. The second memory device 114 stores an instruction that replaces an instruction stored in the first memory device 113, and may also store an independent instruction, thereby flexibly managing instructions stored in a memory device.

The above description can be implemented as, for example, address control circuits including an address register, methods of operating the same, and storage controllers including the same. The above description can also be implemented as, for example, an address control circuit that flexibly manages an instruction stored in a memory device, by: storing a replacement instruction in a memory device, in which the instruction is capable of being easily replaced or added; receiving an address from a processor; determining whether the received address is a replacement target; and providing a replace address to the memory device when the received address is the replacement target.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to examples thereof, it will be apparent to those of ordinary skill in the art that various changes and modifications may be made thereto without departing from the spirit and scope of the present disclosure as set forth in the following claims.

What is claimed is:

1. A storage controller comprising:
a processor;
a first memory device configured to store a first instruction corresponding to a first address;
a second memory device; and
an address control circuit comprising an address register,
wherein the address control circuit is configured to:
receive the first address from the processor,
determine whether the address register indicates that the first instruction is replaced,
in response to determining that the address register does not indicate that the first instruction is replaced, provide the first address to the first memory device, and
in response to determining that the address register indicates that the first instruction is replaced, provide a first replace address to the second memory device based on first address replacement information stored in the address register, wherein the first replace address corresponds to a first replacement instruction, stored in the second memory device, that replaces the first instruction.

2. The storage controller of claim 1, wherein the address control circuit includes an address compare circuit and an address select circuit,
wherein the address compare circuit is configured to, in response to determining that the address register does not indicate that the first instruction is replaced, provide a miss signal to the address select circuit, and
wherein the address select circuit is configured to provide the first address to the first memory device in response to the miss signal.

3. The storage controller of claim 2, wherein the address select circuit is further configured to provide the first address to the second memory device in response to the miss signal.

4. The storage controller of claim 1, wherein the address control circuit includes an address compare circuit and an address select circuit,
wherein the address compare circuit is configured to, in response to determining that the address register indicates that the first instruction is replaced, provide a hit signal to the address select circuit, and
wherein the address select circuit is configured to provide the first replace address to the second memory device in response to the hit signal.

5. The storage controller of claim 1, wherein the first address replacement information includes mapping information between the first address and the first replace address.

6. The storage controller of claim 1, wherein the first memory device is configured to provide the first instruction to the processor based on receiving the first address.

7. The storage controller of claim 1, wherein the second memory device is configured to provide the first replacement instruction to the processor based on receiving the first replace address.

8. The storage controller of claim 1, wherein the address register includes a plurality of unit registers that respectively correspond to addresses of the second memory device, and
wherein a first unit register of the plurality of unit registers corresponds to the first replace address, and
wherein the first address replacement information is configured to determine that the address register indicates that the first instruction is replaced by determining that the first address is stored in the first unit register.

9. The storage controller of claim 1, wherein the first memory device is a Read Only Memory (ROM), and
wherein the second memory device is a Random Access Memory (RAM).

10. The storage controller of claim 1, wherein the first memory device is configured to store a second instruction corresponding to a second address, and
wherein the processor is configured to:
register second address replacement information of the second address in the address register of the address control circuit; and
store a second replacement instruction, corresponding to a second replace address, in the second memory device.

11. The storage controller of claim 10, wherein the processor is configured to receive the second replacement instruction from a host device or a non-volatile memory device before registering the second address replacement information.

12. The storage controller of claim 1, wherein the processor is configured to:
delete the first address replacement information in the address register; and
delete the first replacement instruction in the second memory device.

13. The storage controller of claim 1, wherein the address control circuit is configured to determine whether the address register indicates that the first instruction is replaced by determining whether the first address replacement information is stored in the address register.

14. An address control circuit configured to:
receive a first address from a processor;
determine whether first address replacement information of the first address is registered in an address register of the address control circuit;
in response to determining that the first address replacement information is not registered, provide the first address to a first memory device; and
in response to determining that the first address replacement information is registered, provide a first replace address corresponding to the first address to a second memory device based on the first address replacement information.

15. The address control circuit of claim 14, wherein the address control circuit includes an address compare circuit and an address select circuit,
wherein the address compare circuit is configured to, in response to determining that the first address replacement information is not registered, provide a miss signal to the address select circuit, and
wherein the address select circuit is configured to provide the first address to the first memory device in response to the miss signal.

16. The address control circuit of claim 14, wherein the address control circuit includes an address compare circuit and an address select circuit,
wherein the address compare circuit is configured to, in response to determining that the first address replacement information is registered, provide a hit signal to the address select circuit, and
wherein the address select circuit is configured to provide the first replace address to the second memory device in response to the hit signal.

17. The address control circuit of claim 14, wherein the first address replacement information includes mapping information between the first address and the first replace address.

18. An operating method of an address control circuit, the method comprising:
receiving a first address from a processor;
determining whether first address replacement information of the first address is registered in an address register of the address control circuit;
in response to determining that the first address replacement information is not registered, providing the first address to a first memory device; or
in response to determining that the first address replacement information is registered, providing a first replace address corresponding to the first address to a second memory device based on the first address replacement information.

19. The method of claim 18, wherein the address control circuit includes an address compare circuit and an address select circuit,
wherein the determining of whether the first address replacement information of the first address is registered includes determining, by the address compare circuit, whether the first address replacement information is registered in the address register,
wherein the method comprises providing, by the address compare circuit, a miss signal to the address select circuit in response to determining that the first address replacement information is not registered, and
wherein the providing of the first address to the first memory device includes providing, by the address select circuit, the first address to the first memory device in response to the miss signal.

20. The method of claim 18, wherein the address control circuit includes an address compare circuit and an address select circuit,
wherein the determining of whether the first address replacement information of the first address is registered includes determining, by the address compare circuit, whether the first address replacement information is registered in the address register,
wherein the method comprises providing, by the address compare circuit, a hit signal to the address select circuit in response to determining that the first address replacement information is registered, and
wherein the providing of the first replace address to the second memory device includes providing, by the address select circuit, the first replace address to the second memory device in response to the hit signal.
